(19) United States
(12) Patent Application Publication
(10) Pub. No.: US 2026/0221719 A1
(43) Pub. Date: Jul. 30, 2026

(54) OPTICAL MODULATOR INTEGRATED LASER DEVICE

(71) Applicant: SUMITOMO ELECTRIC DEVICE INNOVATIONS, INC., Yokohama-shi (JP)

(72) Inventor: Kyohei MAEKAWA, Kanagaw (JP)

(73) Assignee: SUMITOMO ELECTRIC DEVICE INNOVATIONS, INC., Yokohama-shi (JP)

(21) Appl. No.: 19/578,198

(22) Filed: Mar. 25, 2026

(30) Foreign Application Priority Data
Dec. 12, 2015 (JP) 2025-246348
Mar. 27, 2025 (JP) 2025-054187

(51) Int. Cl. H01S 5/026; H01S 5/02; H01S 5/227

(52) U.S. Cl. CPC H01S 5/0265; H01S 5/0208; H01S 5/227

(57) ABSTRACT

An optical modulator integrated laser device includes a semi-insulating or insulating substrate, a laser section that outputs laser light, an optical modulator section that receives the laser light from the laser section, and an optical waveguide section that optically couples the optical modulator section to the laser section. Each of the laser section, the optical waveguide section, and the optical modulator section has a contact layer, a first cladding layer, an optical waveguide layer, and a second cladding layer. In each of the laser section, the optical waveguide section, and the optical modulator section, the first cladding layer, the optical waveguide layer, and the second cladding layer form a mesa structure extending in the optical waveguide direction. The contact layer includes an under-mesa region located between the mesa structure and the substrate.

### DESCRIPTION

### CROSS REFERENCE TO RELATED APPLICATIONS

Priority is claimed on Japanese Patent Application No. 2025-054187, filed on March 27, 2025, and Japanese Patent Application No. 2025-246348, filed on December 12, 2025, the entire contents of each of which are incorporated herein by reference.

### TECHNICAL FIELD

The present disclosure relates to an optical modulator integrated laser device.

### BACKGROUND

Japanese Unexamined Patent Publication No. 2002-277840 discloses an optical modulator integrated laser device that includes a laser section and an electro-absorption type optical modulator section. The optical modulator section includes an n-electrode and a p-electrode. A non-inverted signal and an inverted signal, which form a differential signal, are input to the n-electrode and the p-electrode, respectively.

### SUMMARY

An optical modulator integrated laser device according to an aspect of the present disclosure includes: a semi-insulating or insulating substrate; a laser section that is provided on the substrate and outputs laser light; an optical modulator section that is provided on the substrate and receives the laser light from the laser section; and an optical waveguide section that is provided on the substrate and optically couples the optical modulator section to the laser section. Each of the laser section, the optical waveguide section, and the optical modulator section has: a contact layer of a first conductivity type provided on the substrate; a first cladding layer of the first conductivity type provided on the contact layer; an optical waveguide layer provided on the first cladding layer; and a second cladding layer of a second conductivity type provided on the optical waveguide layer. In each of the laser section, the optical waveguide section, and the optical modulator section, the first cladding layer, the optical waveguide layer, and the second cladding layer form a mesa structure extending in an optical waveguide direction. The contact layer includes an under-mesa region located between the mesa structure and the substrate. A width of the under-mesa region of the optical waveguide section in a first direction along the substrate which is perpendicular to the optical waveguide direction of the optical waveguide layer is smaller than both a width of the under-mesa region of the laser section in the first direction and a width of the under-mesa region of the optical modulator section in the first direction.

### BRIEF DESCRIPTION OF THE DRAWINGS

FIG. 1 is a plan view showing an optical modulator integrated laser device according to an embodiment of the present disclosure.

FIG. 2 is a drawing schematically showing a cross section taken along the line II-II in FIG. 1.

FIG. 3 is a drawing schematically showing a cross section taken along the line III-III in FIG. 1.

FIG. 4 is a drawing schematically showing a cross section taken along the line IV-IV in FIG. 1.

FIG. 5 is a drawing showing parts of FIGS. 2, 3, and 4 in an enlarged manner.

FIG. 6 is a drawing showing a further enlarged view of a part of FIG. 5.

FIG. 7 is a drawing schematically showing a cross section taken along the line VII-VII in FIG. 1.

FIG. 8 is a drawing schematically showing a cross section taken along the line VIII-VIII in FIG. 1.

FIG. 9 is a drawing showing a step of growing a contact layer, an etching stop layer, a first cladding layer, a light absorption layer (or an optical waveguide core layer), and a second cladding layer on a substrate.

FIG. 10 is a drawing showing a step of removing an insulating film on a mesa structure and in a region around the mesa structure.

FIG. 11 is a circuit diagram showing an equivalent circuit of an optical modulator integrated laser device used in a simulation.

FIG. 12 is a graph showing an example of the relationship between an S-parameter of a laser section and a frequency used in the simulation.

FIG. 13 is a graph showing the distribution of a modulation current, for each frequency, that the laser section receives due to interference from a modulation signal of an optical modulator section.

FIG. 14 is a graph showing the distribution of a modulation current, for each frequency, that the laser section receives due to interference from a modulation signal of an optical modulator section.

FIG. 15 is a graph showing the distribution of a modulation current, for each frequency, that the laser section receives due to interference from a modulation signal of an optical modulator section.

FIG. 16 is a graph showing the distribution of fluctuations in output from the laser section, for each frequency, when the isolation resistance is 100 Ω.

FIG. 17 is a graph showing the distribution of fluctuations in output from the laser section, for each frequency, when the isolation resistance is 300 Ω.

FIG. 18 is a graph showing the distribution of fluctuations in output from the laser section, for each frequency, when the isolation resistance is 1 kΩ.

FIG. 19 is a graph showing relative values of the frequency distribution of output fluctuations shown in FIG. 16.

FIG. 20 is a graph showing relative values of the frequency distribution of output fluctuations shown in FIG. 17.

FIG. 21 is a graph showing relative values of the frequency distribution of output fluctuations shown in FIG. 18.

FIG. 22 is a drawing showing the waveform (eye pattern) of light output from an optical modulator section when the isolation resistance is 100 Ω.

FIG. 23 is a drawing showing the waveform (eye pattern) of light output from an optical modulator section when the isolation resistance is 300 Ω.

FIG. 24 is a drawing showing the waveform (eye pattern) of light output from an optical modulator section when the isolation resistance is 1 kΩ.

FIG. 25 is a graph showing the relationship between the resistance value of an isolation resistor and the modulation amplitude of a drive current flowing through a laser section.

FIG. 26 is a graph showing the relationship between the resistance value of an isolation resistor and TDECQ.

FIG. 27 is a graph showing the relationship between the resistance value of an isolation resistor and the dip depth of an S-parameter.

FIG. 28 is a graph showing the relationship between the width of an under-mesa region of an optical waveguide section and the resistance value of an isolation resistor.

FIG. 29 is a graph showing the relationship between the length of an under-mesa region of an optical waveguide section and the resistance value of an isolation resistor.

FIG. 30 is a plan view showing an optical modulator integrated laser device according to a first Modification.

FIG. 31 is a plan view showing an optical modulator integrated laser device according to a second Modification.

FIG. 32 is a drawing for explaining another structural example of a region in the optical waveguide section where a contact layer has been removed.

FIG. 33 is a drawing for explaining another structural example of a region in the optical waveguide section where a contact layer has been removed.

### DETAILED DESCRIPTION

When performing differential driving of an electro-absorption type optical modulator section, electrical connection is facilitated by providing an electrode pad connected to an n-electrode and an electrode pad connected to a p-electrode on the upper surface of the optical modulator section. For this purpose, for example, it is conceivable to form a lower cladding layer, a light absorption layer, and an upper cladding layer on an insulating or semi-insulating substrate and provide a contact layer between the lower cladding layer and the substrate. In one example, the contact layer and the lower cladding layer are of n-type, and the upper cladding layer is of p-type. In another example, the contact layer and the lower cladding layer are of p-type, and the upper cladding layer is of n-type. Then, for electrical connection, the contact layer is exposed from the lower cladding layer. A non-inverted signal and an inverted signal, which form a differential signal, are input to the contact layer and the upper cladding layer, respectively.

However, in an optical modulator integrated laser device in which a laser section that outputs laser light and the above-described optical modulator section are monolithically integrated on a common substrate, the following problem occurs. In such an optical modulator integrated laser device, a mesa structure for an optical waveguide is formed across the laser section and the optical modulator section. Below the mesa structure, a contact layer is present across the laser section and the optical modulator section. If the resistance (isolation resistance) between the contact layer of the laser section and the contact layer of the optical modulator section is small, a modulation signal applied to the optical modulator section interferes with a bias current supplied to the laser section, thereby degrading the stability of the output from the laser section.

In order to increase the isolation resistance between the contact layer of the laser section and the contact layer of the optical modulator section, it is conceivable to reduce the impurity concentration in a region between the contact layer of the laser section and the contact layer of the optical modulator section or to make the region insulating or semi-insulating. However, in such a structure, it is necessary to change the growth material or growth conditions only for that region. As a result, a step is likely to occur between the optical waveguide layers of the laser section and the optical modulator section and the optical waveguide layer on the region, which may reduce the optical coupling efficiency between the laser section and the optical modulator section.

It is an object of the present disclosure to provide an optical modulator integrated laser device that can increase an isolation resistance between a contact layer of a laser section and a contact layer of an optical modulator section while avoiding a decrease in optical coupling efficiency between the laser section and the optical modulator section.

### [Description of Embodiments of the Present Disclosure]

First, embodiments of the present disclosure will be listed and described.

(1) An optical modulator integrated laser device according to an embodiment of the present disclosure includes: a semi-insulating or insulating substrate; a laser section that is provided on the substrate and outputs laser light; an optical modulator section that is provided on the substrate and receives the laser light from the laser section; and an optical waveguide section that is provided on the substrate and optically couples the optical modulator section to the laser section. Each of the laser section, the optical waveguide section, and the optical modulator section has: a contact layer of a first conductivity type provided on the substrate; a first cladding layer of the first conductivity type provided on the contact layer; an optical waveguide layer provided on the first cladding layer; and a second cladding layer of a second conductivity type provided on the optical waveguide layer. In each of the laser section, the optical waveguide section, and the optical modulator section, the first cladding layer, the optical waveguide layer, and the second cladding layer form a mesa structure extending in an optical waveguide direction. The contact layer includes an under-mesa region located between the mesa structure and the substrate. A width of the under-mesa region of the optical waveguide section in a first direction along the substrate which is perpendicular to the optical waveguide direction of the optical waveguide layer is smaller than both a width of the under-mesa region of the laser section in the first direction and a width of the under-mesa region of the optical modulator section in the first direction.

In the optical modulator integrated laser device according to (1) above, the width of the under-mesa region of the optical waveguide section is smaller than both the width of the under-mesa region of the laser section and the width of the under-mesa region of the optical modulator section. Therefore, it is possible to increase the isolation resistance between the contact layer of the laser section and the contact layer of the optical modulator section. In addition, in order to increase the isolation resistance, it is not necessary to reduce the impurity concentration in a region between the contact layer of the laser section and the contact layer of the optical modulator section, nor is it necessary to make the region insulating or semi-insulating. Therefore, it is possible to avoid a decrease in the optical coupling efficiency between the laser section and the optical modulator section.

(2) In the optical modulator integrated laser device according to (1) above, the width of the under-mesa region of the optical waveguide section in the first direction may be 1 μm or more and 8 μm or less. In this case, the isolation resistance between the contact layer of the laser section and the contact layer of the optical modulator section can be made larger.

(3) In the optical modulator integrated laser device according to (2) above, the width of the under-mesa region of the laser section in the first direction and the width of the under-mesa region of the optical modulator section in the first direction may each be 40 μm or more and 120 μm or less.

(4) In the optical modulator integrated laser device according to any one of (1) to (3) above, a length of the under-mesa region of the optical waveguide section in the optical waveguide direction may be 50 μm or more and 150 μm or less. In this case, the isolation resistance between the contact layer of the laser section and the contact layer of the optical modulator section can be made larger.

(5) In the optical modulator integrated laser device according to any one of (1) to (4) above, the optical waveguide section may further have a semi-insulating or insulating embedding region that embeds both sides of the mesa structure. Then, both ends of the under-mesa region in the first direction may be formed by a recess penetrating the embedding region and the contact layer. In this case, the contact layers on both sides of the under-mesa region can be easily removed to control the width of the under-mesa region.

(6) In the optical modulator integrated laser device according to (5) above, the optical waveguide section may further have a protective mesa structure provided on both sides of the under-mesa region in the first direction. Then, a height of the protective mesa structure with respect to the substrate may be greater than a height of the optical waveguide layer with respect to the substrate. In this case, it is possible to reduce damage to a portion interposed between the recesses during the manufacture of the optical modulator integrated laser device.

(7) In the optical modulator integrated laser device according to any one of (1) to (6) above, the optical modulator section may include a first optical modulator section and a second optical modulator section.

(8) The optical modulator integrated laser device according to any one of (1) to (7) above may further include a tip portion that is provided between the optical modulator section and a light emission end surface on the substrate and has the contact layer, the first cladding layer, the optical waveguide layer, and the second cladding layer. In the tip portion, the first cladding layer, the optical waveguide layer, and the second cladding layer may form a mesa structure extending in the optical waveguide direction, the contact layer may include an under-mesa region located between the mesa structure and the substrate. The width of the under-mesa region of the tip portion in the first direction may be smaller than both the width of the under-mesa region of the laser section in the first direction and the width of the under-mesa region of the optical modulator section in the first direction. In this case, in addition to the isolation resistance between the contact layer of the laser section and the contact layer of the optical modulator section, the isolation resistance on the tip side of the contact layer of the optical modulator section can be further increased.

(9) In the optical modulator integrated laser device according to any one of (1) to (8) above, an isolation resistance between the contact layer of the laser section and the contact layer of the optical modulator section may be 200 Ω or more and 1 kΩ or less. By setting the isolation resistance to 200 Ω or more, it is possible to reduce interference of the modulation signal applied to the optical modulator section with the bias current supplied to the laser section, thereby improving the stability of the output from the laser section. In addition, by setting the isolation resistance to 1 kΩ or less, it is allowed to increase the width of the under-mesa region, thereby facilitating the manufacturing process of the under-mesa region.

### [Details of Embodiments of the Present Disclosure]

Specific examples of the present disclosure will be described below with reference to the accompanying drawings. The present disclosure is not limited to these examples, but is defined by the claims, and is intended to include all modifications within the meaning and scope equivalent to the claims. In the following description, the same elements will be denoted by the same reference numerals in the description of the drawings, and repeated description thereof will be omitted.

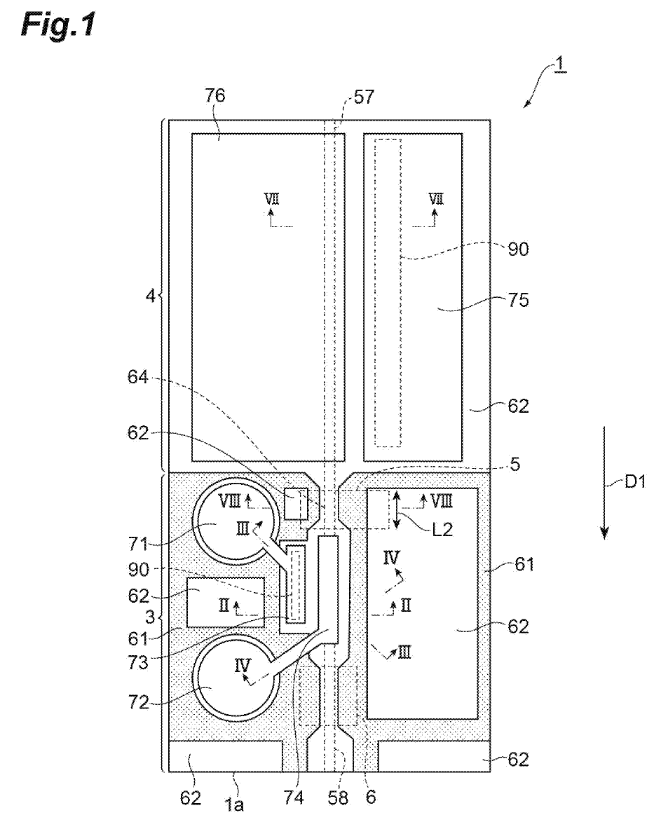

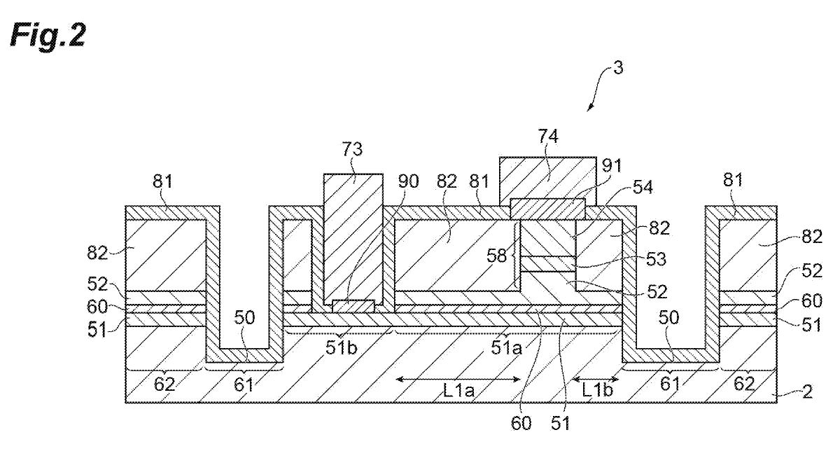

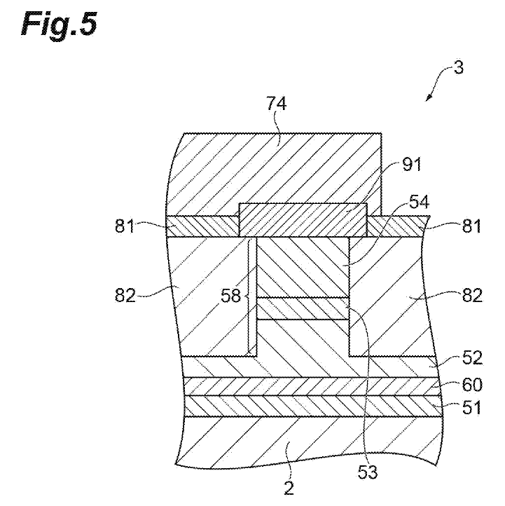

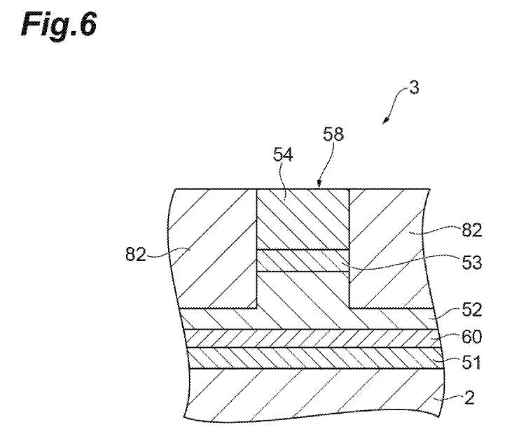

FIG. 1 is a plan view showing an optical modulator integrated laser device 1 according to an embodiment of the present disclosure. FIGS. 2, 3, and 4 are drawings schematically showing cross sections taken along the lines II-II, III-III, and IV-IV in FIG. 1, respectively. FIG. 5 is a drawing showing parts of FIGS. 2, 3, and 4 in an enlarged manner. FIG. 6 is a drawing showing a further enlarged view of a part of FIG. 5.

The optical modulator integrated laser device 1 according to the present embodiment includes an optical modulator section 3, a laser section 4, and an optical waveguide section 5. The laser section 4 outputs laser light. The optical modulator section 3 receives the laser light from the laser section 4 and modulates the laser light. The optical waveguide section 5 is provided between the optical modulator section 3 and the laser section 4, and optically couples the optical modulator section 3 to the laser section 4. The optical modulator section 3, the laser section 4, and the optical waveguide section 5 are monolithically provided on a common substrate 2. The laser section 4 and the optical waveguide section 5 are adjacent to each other along an optical waveguide direction D1 on the substrate 2. The optical waveguide section 5 and the optical modulator section 3 are adjacent to each other along the optical waveguide direction D1 on the substrate 2.

The optical modulator section 3 is an electro-absorption type optical modulator, and includes the substrate 2, a contact layer 51, a first cladding layer 52, a light absorption layer 53, and a second cladding layer 54. The substrate 2 has a semi-insulating or insulating property. The substrate 2 contains, for example, a III-V compound semiconductor, and is an InP substrate in one example.

The contact layer 51 is provided on the substrate 2 and has a first conductivity type. The first conductivity type is, for example, n-type. The contact layer 51 contains a semiconductor that is lattice-matched to the substrate 2, and is an n⁺-type InP layer in one example. In the present embodiment, the contact layer 51 is provided on the substrate 2 and is in contact with the substrate 2. The thickness of the contact layer 51 is smaller than the thickness of the first cladding layer 52. The thickness of the contact layer 51 is 100 nm or more and 1000 nm or less, and is 400 nm in one example. The impurity concentration of the contact layer 51 is higher than the impurity concentration of the first cladding layer 52. The impurity concentration of the contact layer 51 is 1 × 10¹⁸ cm⁻³ or more and 2 × 10¹⁹ cm⁻³ or less, and is 8 × 10¹⁸ cm⁻³ in one example.

The first cladding layer 52 is provided on the contact layer 51 and has a first conductivity type. The first cladding layer 52 contains a semiconductor that is lattice-matched to the contact layer 51, and is an n-type InP layer in one example. In the present embodiment, the first cladding layer 52 is provided on the contact layer 51 and is in contact with the contact layer 51. The thickness of the first cladding layer 52 is 0.5 μm or more and 2 μm or less, and is 1.2 μm in one example. The impurity concentration of the first cladding layer 52 is 1 × 10¹⁷ cm⁻³ or more and 2 × 10¹⁸ cm⁻³ or less, and is 5 × 10¹⁷ cm⁻³ in one example.

The light absorption layer 53 is an optical waveguide layer in the optical modulator section 3. The light absorption layer 53 is provided on the first cladding layer 52. The band gap of the light absorption layer 53 is smaller than the band gap of the first cladding layer 52. The refractive index of the light absorption layer 53 is greater than the refractive index of the first cladding layer 52. The light absorption layer 53 contains a semiconductor that is lattice-matched to the first cladding layer 52. The light absorption layer 53 may have a multiple quantum well structure. In one example, the light absorption layer 53 is formed by stacking InGaAsP layers or InGaAlAs layers having different compositions. In the present embodiment, the light absorption layer 53 is provided on the first cladding layer 52 and is in contact with the first cladding layer 52.

The second cladding layer 54 is provided on the light absorption layer 53 and has a second conductivity type. The second conductivity type is, for example, p-type. The second cladding layer 54 contains a semiconductor that is lattice-matched to the light absorption layer 53, and is a p-type InP layer in one example. In the present embodiment, the second cladding layer 54 is provided on the light absorption layer 53 and is in contact with the light absorption layer 53. An ohmic electrode 91 is provided on the second cladding layer 54, and a wiring 74 is provided on the ohmic electrode 91.

As shown in FIG. 5, the optical modulator section 3 further includes an etching stop layer 60. The etching stop layer 60 is provided between the contact layer 51 and the first cladding layer 52. In one example, the etching stop layer 60 is in contact with the contact layer 51 and the first cladding layer 52. The etching stop layer 60 is used to stop etching by utilizing a difference in etching rate from the first cladding layer 52 when forming an ohmic electrode in contact with the contact layer 51. The etching stop layer 60 has a first conductivity type. The etching stop layer 60 is, for example, an n-type InGaAsP layer.

The first cladding layer 52, the light absorption layer 53, and the second cladding layer 54 form a mesa structure 58 extending along the optical waveguide direction D1. The width of the mesa structure 58 in a lateral direction is, for example, 1.4 μm. A base end of the mesa structure 58 is present in the first cladding layer 52. Therefore, lower portions of the contact layer 51, the etching stop layer 60, and the first cladding layer 52 also extend outside the mesa structure 58 in plan view.

The contact layer 51 includes an under-mesa region 51a and an electrode contact region 51b. The under-mesa region 51a includes a region located between the mesa structure 58 and the substrate 2 and a peripheral region thereof. In plan view, distances L1a and L1b (see FIG. 2) between ends of the under-mesa region 51a and the mesa structure 58 in a direction perpendicular to the optical waveguide direction D1 and along an upper surface of the substrate 2 (a first direction in the present disclosure; hereinafter referred to as a lateral direction) are, for example, 3 μm or more and 20 μm or less, and are 10 μm in one example. The electrode contact region 51b is a region exposed from the first cladding layer 52 and the etching stop layer 60 for electrical connection with a wiring 73, which will be described later. The electrode contact region 51b is adjacent to the under-mesa region 51a.

The optical modulator section 3 further includes an insulating film 81 and an embedding region 82. The embedding region 82 is provided on both sides of the mesa structure 58 to embed both side surfaces of the mesa structure 58. The embedding region 82 has an insulating or semi-insulating property. The embedding region 82 is, for example, a semi-insulating InP region. The material of the embedding region 82 may be the same as the material of the substrate 2, or may be different from the material of the substrate 2. The insulating film 81 is provided on the embedding region 82 to cover the embedding region 82. The insulating film 81 is, for example, a silicon compound film such as SiO₂ or SiN.

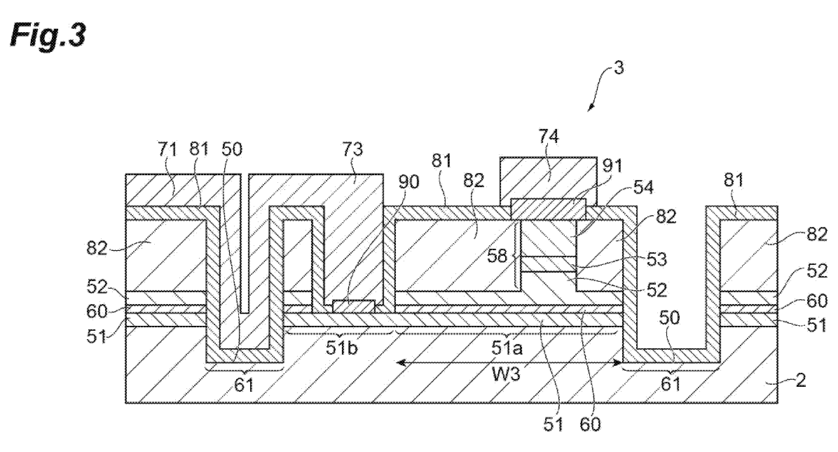

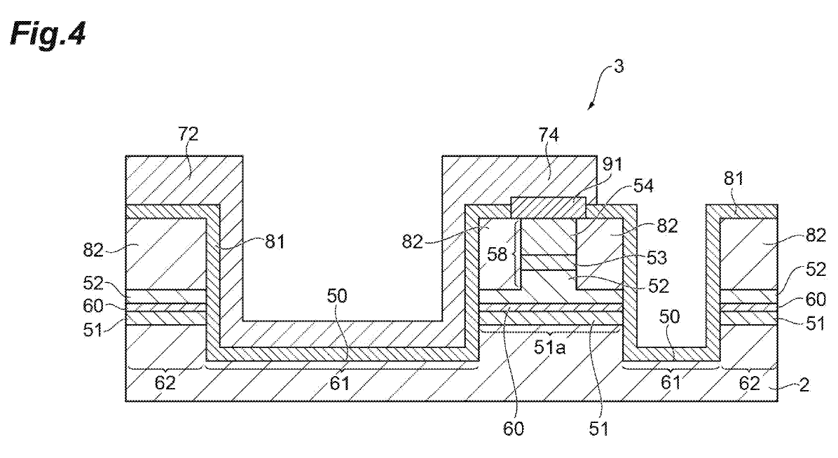

The optical modulator section 3 includes a first electrode pad 71, a second electrode pad 72, a wiring 73, and a wiring 74. The first electrode pad 71, the second electrode pad 72, the wiring 73, and the wiring 74 are metal films, and are gold (Au) films in one example. As shown in FIGS. 3 and 4, the first electrode pad 71 and the second electrode pad 72 are provided above the embedding region 82 and on the insulating film 81. As shown in FIG. 1, the first electrode pad 71 and the second electrode pad 72 are arranged laterally with respect to the mesa structure 58. In addition, the first electrode pad 71 and the second electrode pad 72 are arranged side by side along the optical waveguide direction D1. The planar shapes of the first electrode pad 71 and the second electrode pad 72 are, for example, circular.

The wiring 73 electrically connects the first electrode pad 71 and the contact layer 51 to each other. The wiring 73 includes an ohmic electrode 90, which is a portion provided on the electrode contact region 51b of the contact layer 51 to make ohmic contact with the electrode contact region 51b, and a portion connected to the first electrode pad 71. Portions of the wiring 73 other than the portion in contact with the electrode contact region 51b are provided on the insulating film 81. The wiring 74 electrically connects the second electrode pad 72 and the second cladding layer 54 to each other. The wiring 74 includes an ohmic electrode 91, which is a portion provided on the second cladding layer 54 to make ohmic contact with the second cladding layer 54, and a portion connected to the second electrode pad 72. Portions of the wiring 74 other than the portion in contact with the second cladding layer 54 are provided on the insulating film 81.

A recess 50 is formed in the embedding region 82. The recess 50 penetrates the embedding region 82, the first cladding layer 52, the etching stop layer 60, and the contact layer 51. The recess 50 is formed to partially remove the contact layer 51 on the substrate 2. In FIG. 1, a region 61 where the contact layer 51 has been removed is indicated by stippling. That is, the region 61 is a region where the recess 50 is formed. As shown in FIG. 1, an integrated region formed by the under-mesa region 51a and the electrode contact region 51b is interposed between the regions 61 in the lateral direction. In the present embodiment, the region 61 reaches a light emission end surface 1a. As a result, the under-mesa region 51a is interposed between the regions 61 up to the light emission end surface 1a. The insulating film 81 is provided on the surface of the recess 50.

A protective mesa structure 62 is provided on the substrate 2. The protective mesa structure 62 is a region where the contact layer 51 has not been removed, other than the under-mesa region 51a and the electrode contact region 51b. No recess 50 is formed in the protective mesa structure 62. For this reason, the contact layer 51, the etching stop layer 60, the first cladding layer 52, and the embedding region 82 remain, and these form the protective mesa structure 62. The protective mesa structure 62 has an island-like shape that is electrically isolated.

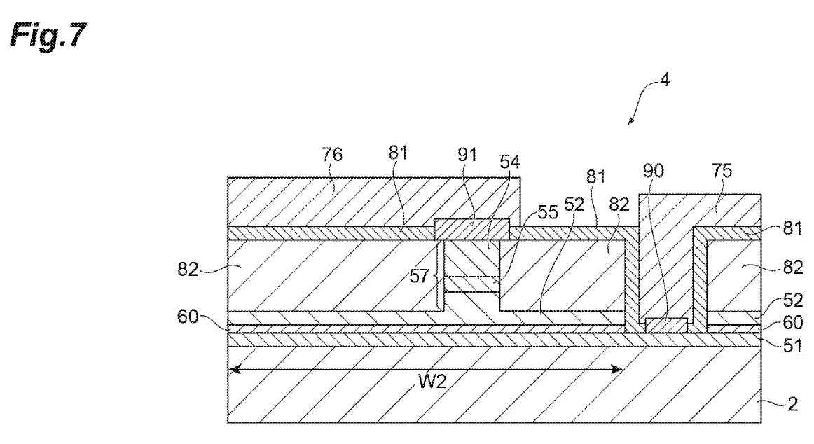

FIG. 7 is a drawing schematically showing a cross section taken along the line VII-VII in FIG. 1. The laser section 4 has the same configuration as the optical modulator section 3 except for the following points. The laser section 4 has an active layer 55 instead of the light absorption layer 53 of the optical modulator section 3. The active layer 55 is an optical waveguide layer in the laser section 4. The first cladding layer 52, the active layer 55, and the second cladding layer 54 form a mesa structure 57 extending along the optical waveguide direction D1. The laser section 4 has an electrode pad 75 instead of the first electrode pad 71 and the wiring 73 of the optical modulator section 3. The laser section 4 has an electrode pad 76 instead of the second electrode pad 72 and the wiring 74 of the optical modulator section 3. The electrode pad 75 is provided above the embedding region 82 and on the insulating film 81, and extends to one side of the mesa structure 57. The ohmic electrode 90 of the electrode pad 75 makes ohmic contact with an exposed portion of the contact layer 51. The electrode pad 76 is provided above the embedding region 82 and on the insulating film 81, and extends to the other side of the mesa structure 57. The ohmic electrode 91 of the electrode pad 76 makes ohmic contact with an exposed portion of the second cladding layer 54. As shown in FIG. 1, in the present embodiment, the region 61 (recess 50) is not formed in the laser section 4. Therefore, the under-mesa region 51a extends to both sides of the mesa structure 57.

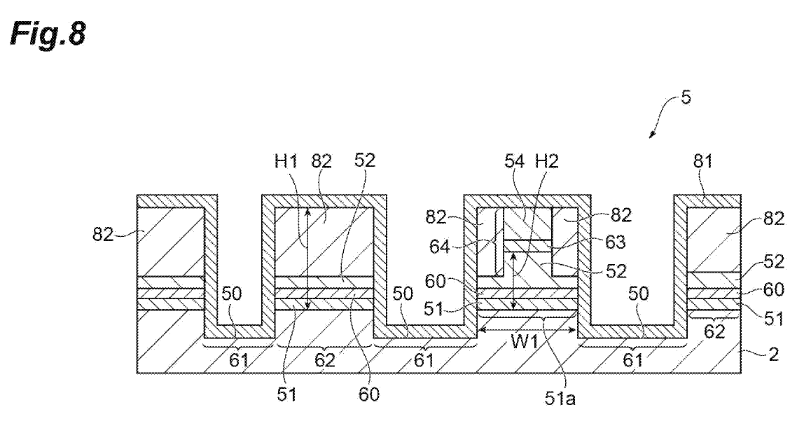

FIG. 8 is a drawing schematically showing a cross section taken along the line VIII-VIII in FIG. 1. The optical waveguide section 5 has the same configuration as the optical modulator section 3 except for the following points. The optical waveguide section 5 has an optical waveguide core layer 63 instead of the light absorption layer 53 of the optical modulator section 3. The optical waveguide core layer 63 is an optical waveguide layer in the optical waveguide section 5. The first cladding layer 52, the optical waveguide core layer 63, and the second cladding layer 54 form a mesa structure 64 extending along the optical waveguide direction D1. The optical waveguide section 5 does not have an electrode pad or a wiring. Therefore, the upper surface of the second cladding layer 54 is covered with the insulating film 81, and the contact layer 51 is not exposed from the first cladding layer 52.

In the optical waveguide section 5, the contact layer 51 includes the under-mesa region 51a located between the mesa structure 64 and the substrate 2. However, the width W1 of the under-mesa region 51a of the optical waveguide section 5 in the lateral direction is smaller than both the width W2 of the under-mesa region 51a of the laser section 4 in the lateral direction (see FIG. 7) and the width W3 of the under-mesa region 51a of the optical modulator section 3 in the lateral direction (see FIG. 3). The width W1 of the under-mesa region 51a of the optical waveguide section 5 in the lateral direction is, for example, 1 μm or more and 8 μm or less. The width W1 may be, for example, 3 μm or more, or 6 μm or less. The length L2 (see FIG. 1) of the under-mesa region 51a of the optical waveguide section 5 in the optical waveguide direction D1 is, for example, 50 μm or more and 150 μm or less.

Also in the optical waveguide section 5, the semi-insulating or insulating embedding region 82 embeds both sides of the mesa structure 64. Then, the under-mesa region 51a is interposed, in the lateral direction, between the regions 61 where the contact layer 51 has been removed. That is, both ends of the under-mesa region 51a in the lateral direction are formed by the recess 50 that penetrates the embedding region 82 and the contact layer 51.

The optical waveguide section 5 also has the protective mesa structure 62 similar to the optical modulator section 3. The protective mesa structure 62 is provided on both sides of the under-mesa region 51a in the lateral direction. The height H1 of these protective mesa structures 62 with respect to the upper surface of the substrate 2 is greater than the height H2 of the optical waveguide core layer 63 with respect to the upper surface of the substrate 2 (see FIG. 8). In one example, the height H1 of the protective mesa structure 62 is approximately equal to the height of the insulating film 81 on the mesa structure 64 with respect to the substrate 2. The protective mesa structure 62 is not limited to a structure including the contact layer 51 as in the illustrated example, but may be configured, for example, by forming the embedding region 82 directly on the substrate 2.

The optical modulator integrated laser device 1 further includes a tip portion 6. The tip portion 6 is provided between the optical modulator section 3 and the light emission end surface 1a on the substrate 2, and includes the contact layer 51, the first cladding layer 52, the optical waveguide core layer 63, and the second cladding layer 54. The cross-sectional structure of the tip portion 6 is the same as that of the optical waveguide section 5 described above. That is, in the tip portion 6, the first cladding layer 52, the optical waveguide core layer 63, and the second cladding layer 54 form the mesa structure 64 extending in the optical waveguide direction D1. Then, the contact layer 51 includes the under-mesa region 51a located between the mesa structure 64 and the substrate 2. The width W1 of the under-mesa region 51a of the tip portion 6 in the lateral direction is smaller than both the width W2 of the under-mesa region 51a of the laser section 4 in the lateral direction and the width W3 of the under-mesa region 51a of the optical modulator section 3 in the lateral direction.

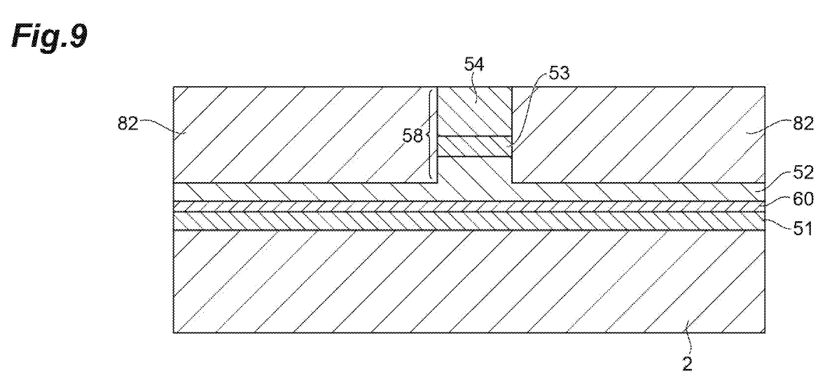

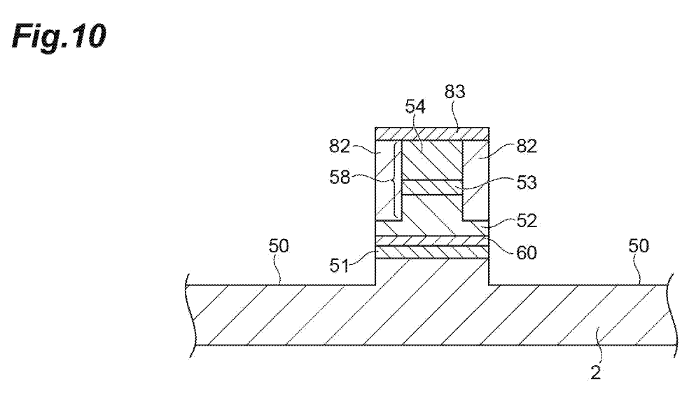

Next, a method for forming the region 61 in the optical modulator section 3, the optical waveguide section 5, and the tip portion 6 will be described. First, as shown in FIG. 9, the contact layer 51, the etching stop layer 60, the first cladding layer 52, the light absorption layer 53 (or the optical waveguide core layer 63), and the second cladding layer 54 are grown on the substrate 2. The mesa structure 58 (or the mesa structure 64) is formed by etching (for example, dry etching). The mesa structure 58 (or the mesa structure 64) is embedded by depositing the embedding region 82 in a region on the substrate 2 excluding the mesa structure 58 (or the mesa structure 64). Thereafter, as shown in FIG. 10, an etching mask 83 is formed on the mesa structure 58 (or on the mesa structure 64) and on the embedding region 82 therearound. A portion of the embedding region 82 exposed from the etching mask 83 and the first cladding layer 52, the etching stop layer 60, and the contact layer 51 therebelow are removed by etching (for example, dry etching) to expose the substrate 2. Through these steps, the region 61 (recess 50) is formed. Thereafter, the insulating film 81 (see FIGS. 2 to 5, 7, and 8) is formed on the embedding region 82.

The effects obtained by the optical modulator integrated laser device 1 according to the present embodiment described above will be described. In the optical modulator integrated laser device 1 according to the present embodiment, the width W1 of the under-mesa region 51a of the optical waveguide section 5 is smaller than both the width W2 of the under-mesa region 51a of the laser section 4 and the width W3 of the under-mesa region 51a of the optical modulator section 3. As a result, it is possible to increase the isolation resistance between the contact layer 51 of the laser section 4 and the contact layer 51 of the optical modulator section 3. In the present embodiment, the isolation resistance is, for example, 200 Ω or more. In addition, in order to increase the isolation resistance, it is not necessary to reduce the impurity concentration in a region between the contact layer 51 of the laser section 4 and the contact layer 51 of the optical modulator section 3, nor is it necessary to make the region insulating or semi-insulating. Therefore, it is possible to avoid a decrease in the optical coupling efficiency between the laser section 4 and the optical modulator section 3.

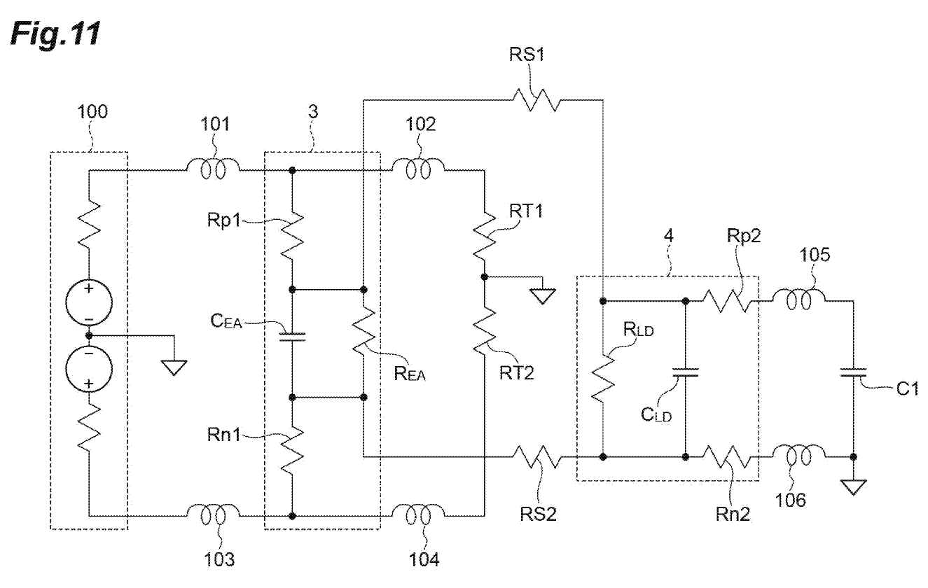

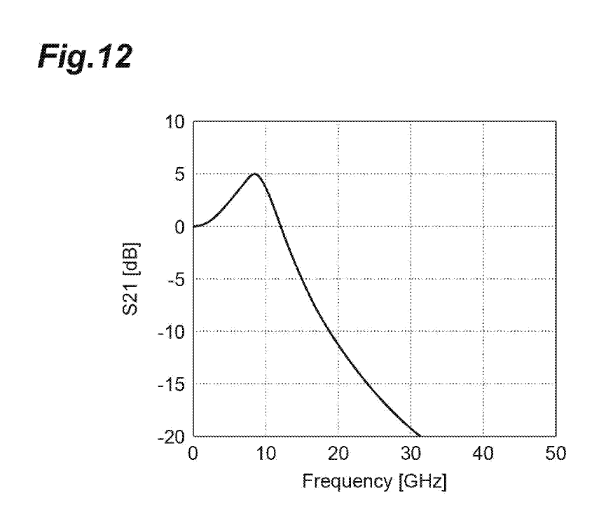

Here, simulation results performed to verify the above effects will be described. FIG. 11 is a circuit diagram showing an equivalent circuit of the optical modulator integrated laser device 1 used in this simulation. In FIG. 11, the optical modulator section 3 is modeled by a parallel circuit of a capacitor C_{EA} and a resistor R_{EA} and a p-side resistor Rp1 and an n-side resistor Rn1 provided at both ends of the parallel circuit. The laser section 4 is modeled by a parallel circuit of a capacitor C_{LD} and a resistor R_{LD} and a p-side resistor Rp2 and an n-side resistor Rn2 provided at both ends of the parallel circuit. The p-side portion of the optical modulator section 3 is connected to a non-inverting terminal of a differential signal source 100 through a wiring (indicated by an inductor symbol) 101, and is also connected to a termination resistor RT1 through a wiring 102. The n-side portion of the optical modulator section 3 is connected to an inverting terminal of the differential signal source 100 through a wiring 103, and is also connected to a termination resistor RT2 through a wiring 104. The p-side portion of the laser section 4 is connected to the p-side portion of the optical modulator section 3 through an isolation resistor RS1, and is also connected to a bias wiring 105. The n-side portion of the laser section 4 is connected to the n-side portion of the optical modulator section 3 through an isolation resistor RS2, and is also connected to a bias wiring 106. The isolation resistor RS2 is a resistor due to the under-mesa region 51a of the optical waveguide section 5. The capacitor C1 is a bypass capacitor for removing noise from the bias voltage. FIG. 12 is a graph showing an example of the relationship between an S-parameter S21 of the laser section 4 and a frequency used in this simulation.

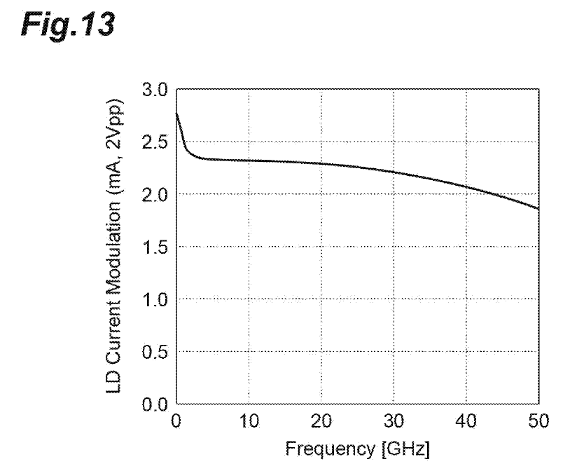

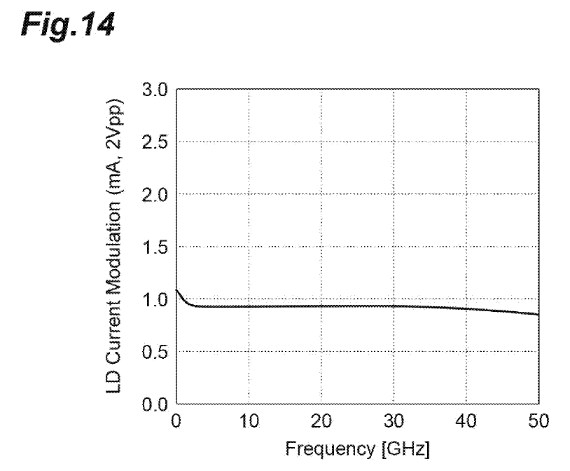

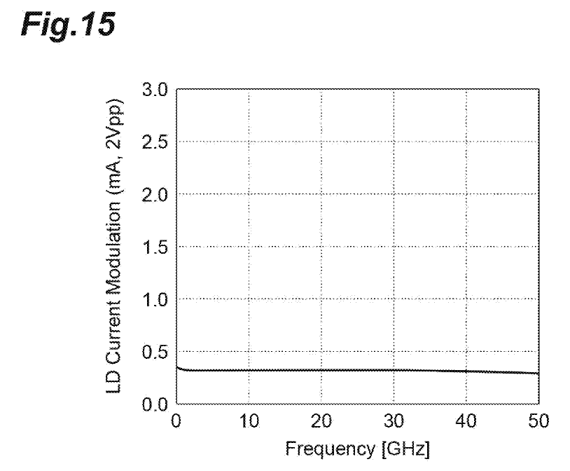

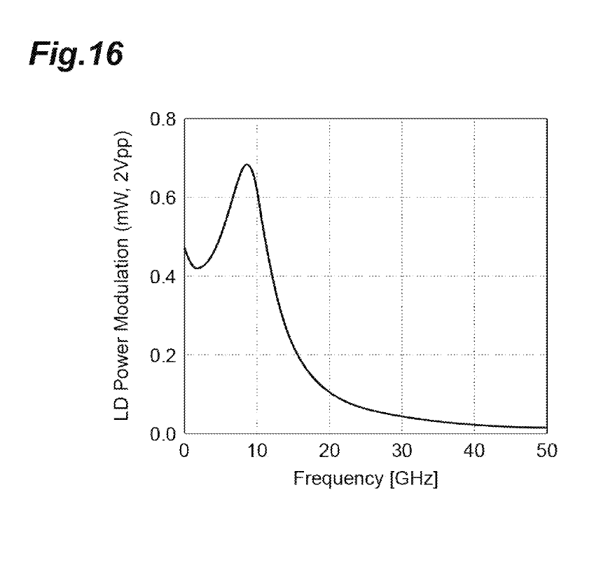

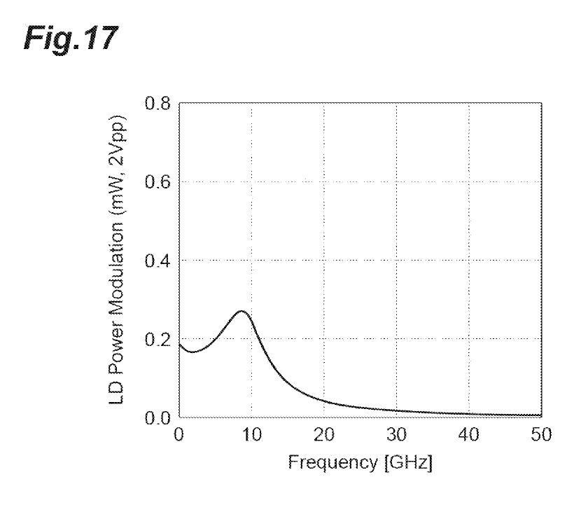

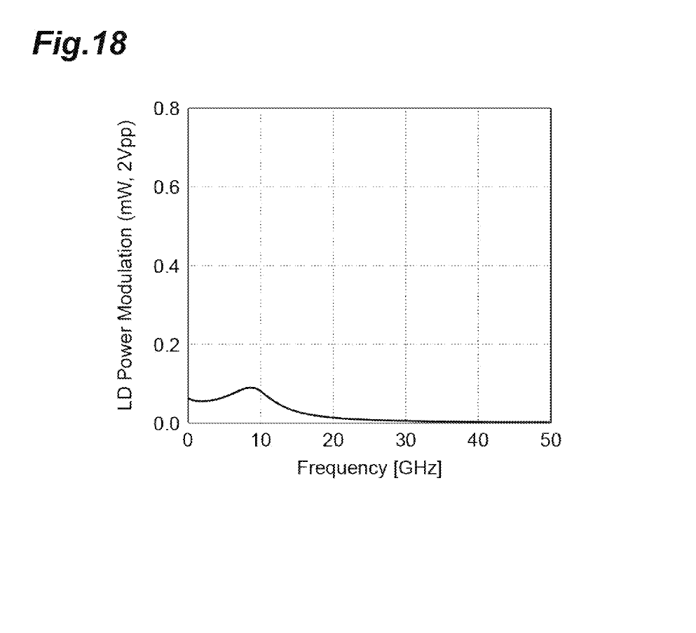

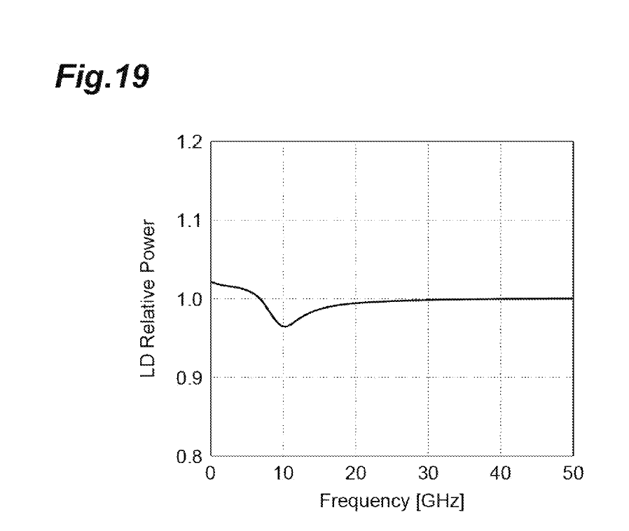

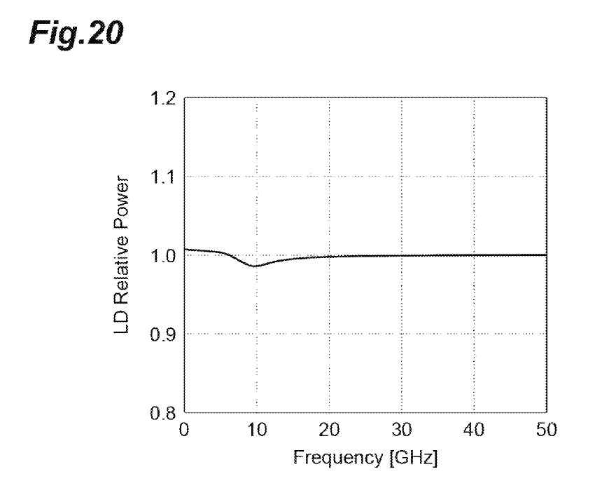

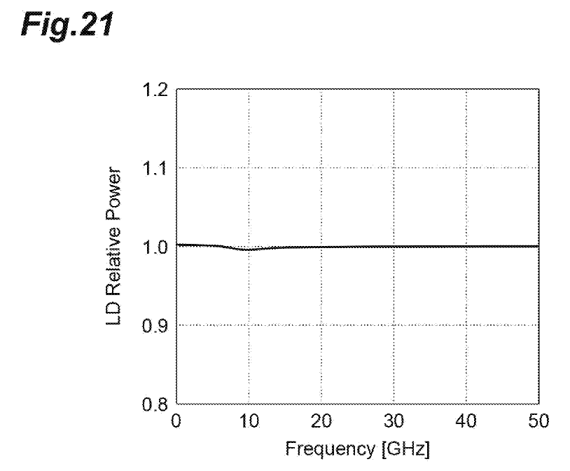

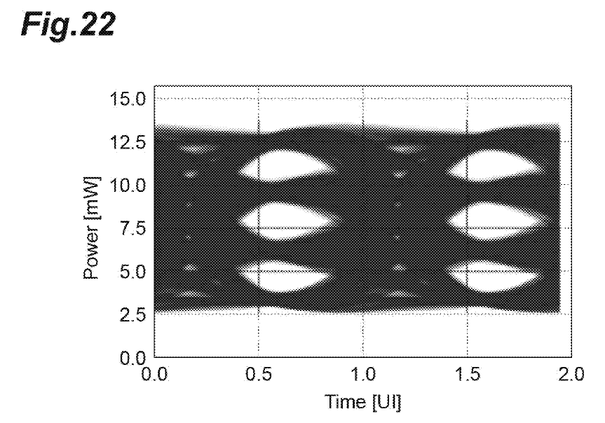

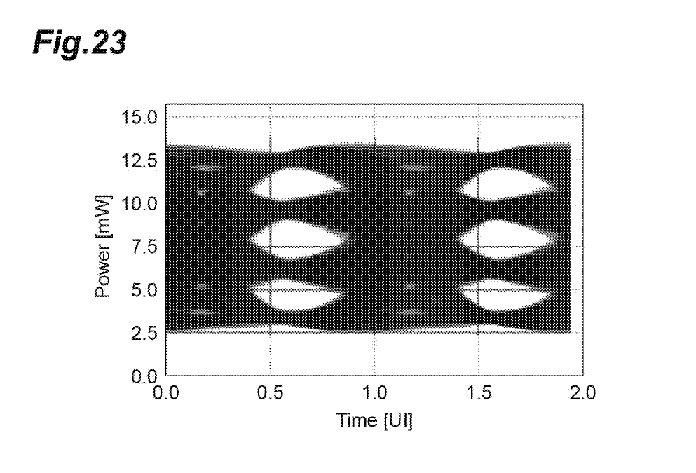

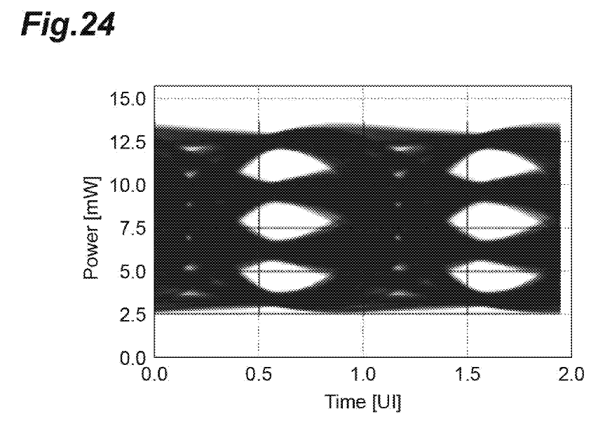

FIGS. 13, 14, and 15 are graphs showing the distribution of a modulation current, for each frequency, that the laser section 4 receives due to interference from the modulation signal of the optical modulator section 3. FIGS. 13, 14, and 15 show cases where the isolation resistor RS2 has resistance values of 100 Ω, 300 Ω, and 1 kΩ, respectively. FIGS. 16, 17, and 18 are graphs showing the distribution of fluctuations in output from the laser section 4, for each frequency, when the isolation resistor RS2 has resistance values of 100 Ω, 300 Ω, and 1 kΩ, respectively. FIGS. 19, 20, and 21 are graphs showing relative values of the frequency distribution of output fluctuations shown in FIGS. 16, 17, and 18 respectively. FIGS. 22, 23, and 24 are drawings showing the waveform (eye pattern) of light output from the optical modulator section 3 when the isolation resistor RS2 has resistance values of 100 Ω, 300 Ω, and 1 kΩ, respectively.

Referring to the above simulation results, it can be seen that as the resistance value of the isolation resistor RS2 increases, fluctuations in the output from the laser section 4 due to interference from the modulation signal of the optical modulator section 3 decrease. In particular, since the difference between the case where the isolation resistor RS2 has a resistance value of 100 Ω and the case where the isolation resistor RS2 has a resistance value of 300 Ω is significant, one criterion can be that the isolation resistor RS2 has a resistance value of 200 Ω or more, which is in between the two cases. In this manner, since the resistance value of the isolation resistor RS2, that is, the resistance due to the under-mesa region 51a of the optical waveguide section 5, is large, interference of the modulation signal applied to the optical modulator section 3 with the bias current supplied to the laser section 4 can be reduced, thereby improving the stability of the output from the laser section 4.

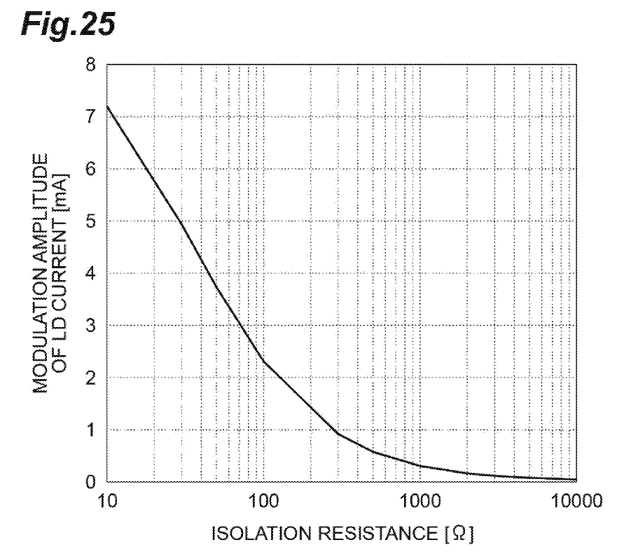

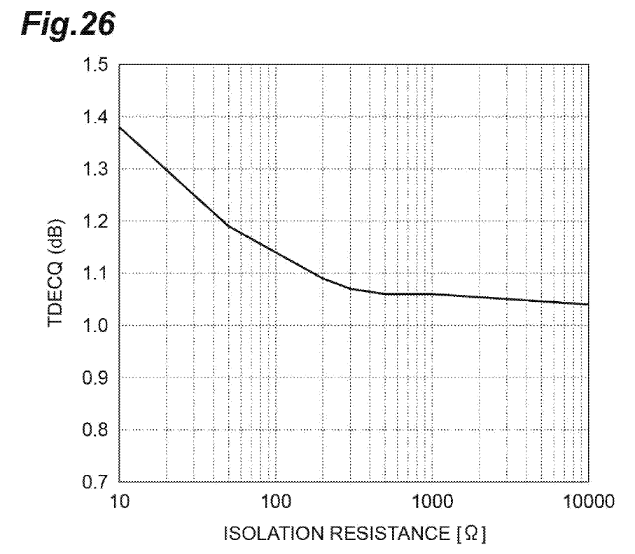

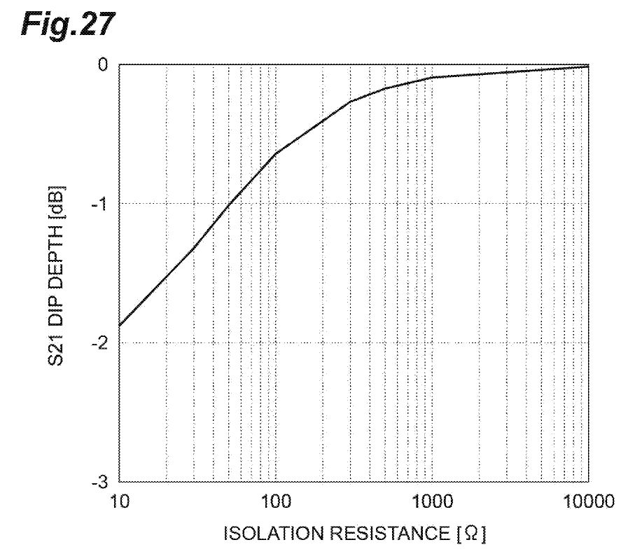

Here, the Transmitter and Dispersion Eye Closure Quaternary (TDECQ), which is an index indicating the degree of distortion or degradation of the optical signal in the above simulation results, will be evaluated. FIG. 25 is a graph showing the relationship between the resistance value (Ω) of the isolation resistor RS2 and the modulation amplitude (mA) of a drive current flowing through the laser section 4. FIG. 26 is a graph showing the relationship between the resistance value (Ω) of the isolation resistor RS2 and the TDECQ (dB). FIG. 27 is a graph showing the relationship between the resistance value (Ω) of the isolation resistor RS2 and the dip depth (dB) of the S-parameter S21. As shown in these graphs, when the isolation resistor RS2 has a resistance value of 200 Ω or more, the amount of degradation in TDECQ is suppressed to less than 0.1 dB, and the dip depth of the S-parameter S21 is suppressed to less than 0.5 dB. Therefore, the influence on the optical waveform quality is suppressed to be sufficiently small.

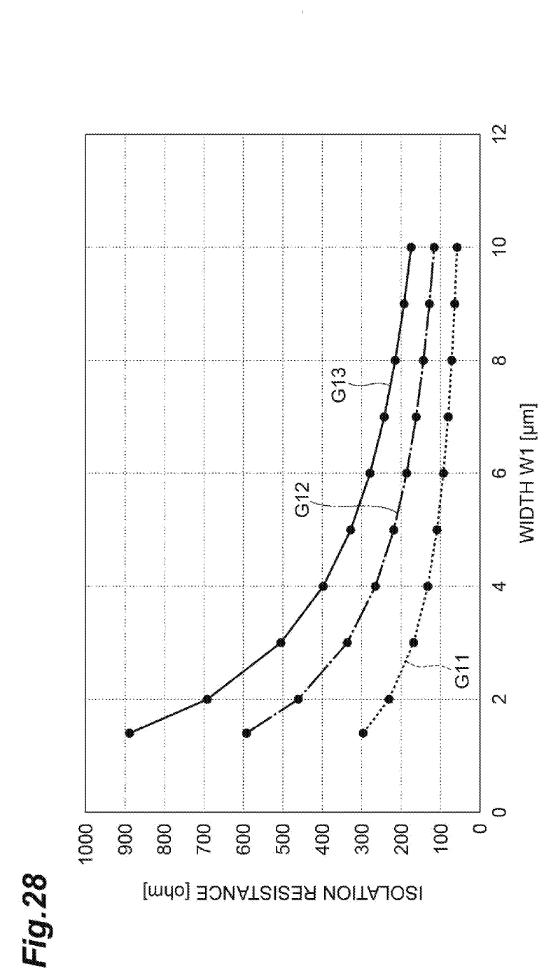

FIG. 28 is a graph showing the relationship between the width W1 of the under-mesa region 51a of the optical waveguide section 5 and the resistance value of the isolation resistor RS2. In FIG. 28, curves G11, G12, and G13 show cases where the length L2 of the under-mesa region 51a of the optical waveguide section 5 is 40 μm, 80 μm, and 120 μm, respectively. Referring to this graph, it can be seen that when the length L2 is 120 μm or more, the resistance value of the isolation resistor RS2 is 200 Ω or more if the width W1 is 8 μm or less. That is, as in the present embodiment, the width W1 of the under-mesa region 51a of the optical waveguide section 5 may be 8 μm or less. In this case, the resistance value of the isolation resistor RS2 between the contact layer 51 of the laser section 4 and the contact layer 51 of the optical modulator section 3 can be made larger. From this graph, when the length L2 is 80 μm or more, the resistance value of the isolation resistor RS2 is 200 Ω or more if the width W1 is 5 μm or less. When the length L2 is 40 μm or more, the resistance value of the isolation resistor RS2 is 200 Ω or more if the width W1 is 2 μm or less. The resistance value of the isolation resistor RS2 is, for example, 1 kΩ or less. A case where the resistance value of the isolation resistor RS2 is greater than 1 kΩ is also allowed. In such a case, however, the width W1 of the under-mesa region 51a is, for example, less than 2 μm. That is, it is necessary to form the under-mesa region 51a so that the width W1 is smaller than the width of the optical waveguide core layer 63. When the resistance value of the isolation resistor RS2 is 1 kΩ or less, it is allowed to increase the width W1 of the under-mesa region 51a, thereby facilitating the manufacturing process of the under-mesa region 51a.

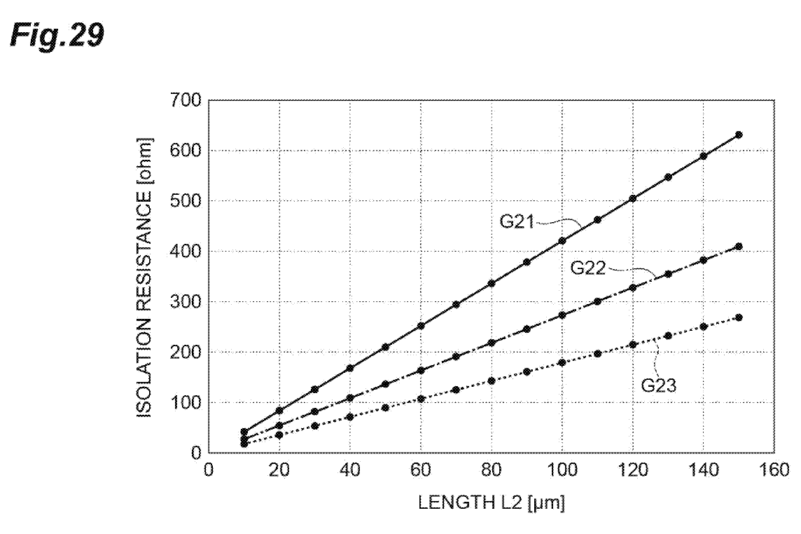

FIG. 29 is a graph showing the relationship between the length L2 of the under-mesa region 51a of the optical waveguide section 5 and the resistance value of the isolation resistor RS2. In FIG. 29, straight lines G21, G22, and G23 show cases where the width W1 of the under-mesa region 51a of the optical waveguide section 5 is 3 μm, 5 μm, and 8 μm, respectively. Referring to this graph, it can be seen that when the width W1 is 3 μm or less, the resistance value of the isolation resistor RS2 is 200 Ω or more if the length L2 is 50 μm or more. That is, as in the present embodiment, the length L2 of the under-mesa region 51a of the optical waveguide section 5 may be 50 μm or more. In this case, the resistance value of the isolation resistor RS2 between the contact layer 51 of the laser section 4 and the contact layer 51 of the optical modulator section 3 can be made larger. From this graph, when the width W1 is 5 μm or less, the resistance value of the isolation resistor RS2 is 200 Ω or more if the length L2 is 80 μm or more. When the width W1 is 8 μm or less, the resistance value of the isolation resistor RS2 is 200 Ω or more if the length L2 is 120 μm or more.

From the graphs shown in FIGS. 28 and 29, the ratio of the width W1 to the length L2 (W1/L2) may be smaller than, for example, 7/100. In this case, the isolation resistor RS2 can be set to have a resistance value of 200 Ω or more.

As in the present embodiment, the optical waveguide section 5 may have the semi-insulating or insulating embedding region 82 that embeds both sides of the mesa structure 64. In addition, by the recess 50 that penetrates the embedding region 82 and the contact layer 51, both ends of the under-mesa region 51a in the lateral direction may be formed. In this case, the width W1 of the under-mesa region 51a can be controlled by easily removing the contact layer 51 on both sides of the under-mesa region 51a.

As in the present embodiment, the optical waveguide section 5 may have the protective mesa structure 62 provided on both sides of the under-mesa region 51a. In addition, the height H1 of the protective mesa structure 62 with respect to the substrate 2 may be greater than the height H2 of the optical waveguide core layer 63 with respect to the substrate 2. In this case, since stress generated during the manufacture of the optical modulator integrated laser device 1 is dispersed, it is possible to reduce damage to a portion interposed between the recesses 50.

As in the present embodiment, the optical modulator integrated laser device 1 may further include the tip portion 6. The width W1 of the under-mesa region 51a of the tip portion 6 may be smaller than both the width W2 of the under-mesa region 51a of the laser section 4 and the width W3 of the under-mesa region 51a of the optical modulator section 3. In this case, in addition to the isolation resistance between the contact layer 51 of the laser section 4 and the contact layer 51 of the optical modulator section 3, the isolation resistance on the tip side of the contact layer 51 of the optical modulator section 3 can be further increased.

### (First Modification)

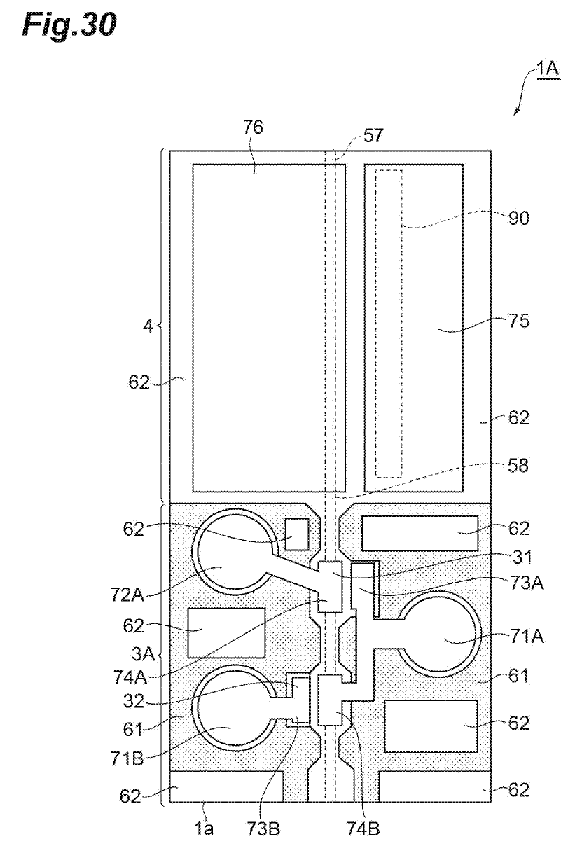

FIG. 30 is a plan view showing an optical modulator integrated laser device 1A according to a first Modification. The optical modulator integrated laser device 1A according to this Modification is different from the above embodiment in that the optical modulator integrated laser device 1A includes an optical modulator section 3A instead of the optical modulator section 3, but is the same as the above embodiment in other respects. The optical modulator section 3A includes a first optical modulator section 31 and a second optical modulator section 32 that are optically coupled in series. Therefore, the optical modulator section 3A has electrode pads 71A, 71B, and 72A and wirings 73A, 73B, 74A, and 74B instead of the first electrode pad 71 and second electrode pad 72 and the wirings 73 and 74 in the above embodiment.

The electrode pad 72A is an electrode pad belonging to the first optical modulator section 31. The electrode pad 71B is an electrode pad belonging to the second optical modulator section 32. The electrode pad 71A is an electrode pad belonging to both the first optical modulator section 31 and the second optical modulator section 32. In the first optical modulator section 31, the electrode pad 71A corresponds to the first electrode pad, and the electrode pad 72A corresponds to the second electrode pad. In the second optical modulator section 32, the electrode pad 71B corresponds to the first electrode pad, and the electrode pad 71A corresponds to the second electrode pad.

The electrode pads 71A, 71B, and 72A and the wirings 73A, 73B, 74A, and 74B are metal films, and are gold (Au) films in one example. The electrode pads 71A, 71B, and 72A are provided above the embedding region 82 and on the insulating film 81. As shown in FIG. 30, the electrode pad 71A is arranged on one side of the mesa structure 58. The electrode pads 71B and 72A are arranged on the other side of the mesa structure 58. The planar shapes of the electrode pads 71A, 71B, and 72A are, for example, circular.

The wirings 73A and 74A are wirings belonging to the first optical modulator section 31. The wiring 73A electrically connects the electrode pad 71A and the contact layer 51 of the first optical modulator section 31 to each other. The wiring 73A includes a portion, which is provided on the electrode contact region 51b of the contact layer 51 to make ohmic contact with the electrode contact region 51b, and a portion connected to the electrode pad 71A. The wiring 74A electrically connects the electrode pad 72A and the second cladding layer 54 of the first optical modulator section 31 to each other.

The wirings 73B and 74B are wirings belonging to the second optical modulator section 32. The wiring 73B electrically connects the electrode pad 71B and the contact layer 51 of the second optical modulator section 32 to each other. The wiring 73B includes a portion, which is provided on the electrode contact region 51b of the contact layer 51 to make ohmic contact with the electrode contact region 51b, and a portion connected to the electrode pad 71B. The wiring 74B electrically connects the electrode pad 71A and the second cladding layer 54 of the second optical modulator section 32 to each other.

Even when the optical modulator section 3A includes the first optical modulator section 31 and the second optical modulator section 32 as in this Modification, the same effects as in the above embodiment can be obtained by providing the optical waveguide section 5 in the above embodiment.

### (Second Modification)

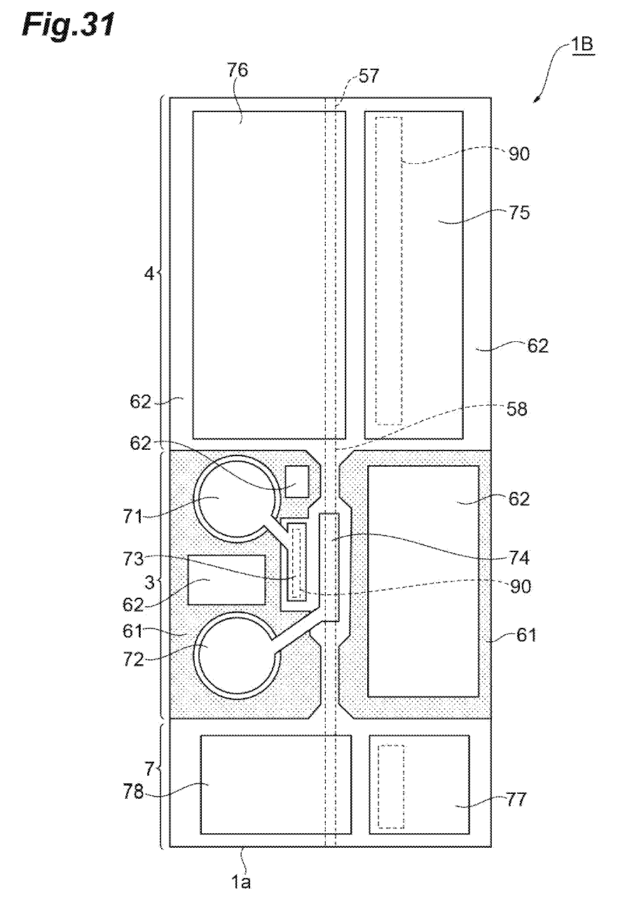

FIG. 31 is a plan view showing an optical modulator integrated laser device 1B according to a second Modification. The optical modulator integrated laser device 1B further includes a semiconductor optical amplifier (SOA) 7 in addition to the same configuration as the optical modulator integrated laser device 1 according to the above embodiment. The semiconductor optical amplifier 7 is monolithically provided on the same substrate 2 as the optical modulator section 3 and the laser section 4. The semiconductor optical amplifier 7 is provided on a side opposite to the laser section 4 with respect to the optical modulator section 3, and is adjacent to the optical modulator section 3 in the optical waveguide direction D1. The semiconductor optical amplifier 7 receives modulated laser light from the optical modulator section 3, amplifies the modulated laser light, and outputs the amplified laser light. The semiconductor optical amplifier 7 has an electrode pad 77 that makes ohmic contact with the contact layer 51 and an electrode pad 78 that makes ohmic contact with the second cladding layer 54. In this Modification as well, since the optical waveguide section 5 in the above embodiment is provided, the same effects as in the above embodiment can be obtained. In addition, since the semiconductor optical amplifier 7 is provided on the same substrate 2 as the optical modulator section 3 and the laser section 4, the optical modulator integrated laser device 1B including the semiconductor optical amplifier 7 can be made smaller. The semiconductor optical amplifier 7 may also be provided in the first Modification described above.

### (Third Modification)

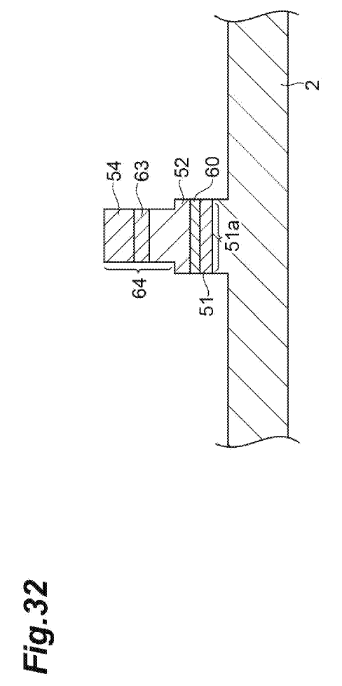

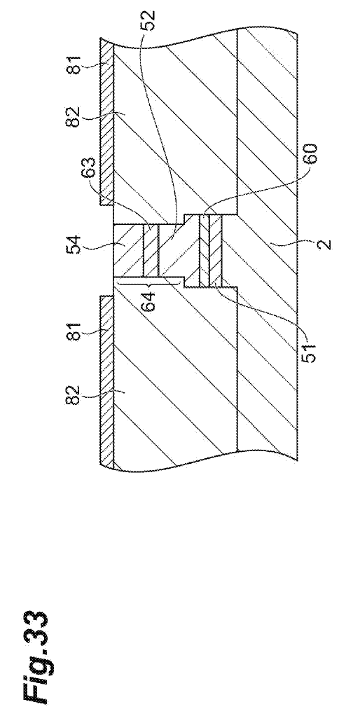

FIGS. 32 and 33 are drawings for explaining another structural example of the region 61 in the optical waveguide section 5 where the contact layer 51 has been removed. In this example, first, as shown in FIG. 32, etching (for example, dry etching) is performed around the under-mesa region 51a of the contact layer 51 to remove the contact layer 51 around the under-mesa region 51a. Then, as shown in FIG. 33, the embedding region 82 is deposited in the etched region, and the insulating film 81 is formed on the embedding region 82. The structure of the region 61 in the optical modulator section 3 may be similar to this. Even with the structure of this Modification, it is possible to obtain the region 61 where the contact layer 51 has been removed. In addition, according to this Modification, the unevenness of the surface of the optical modulator integrated laser device can be reduced, thereby facilitating processes such as forming wirings on the surface.

The optical modulator integrated laser device according to the present disclosure is not limited to the embodiment and its Modifications described above, and various other modifications are possible. For example, the structure of the region where the contact layer has been removed is not limited to the embodiment and its Modifications described above. In the embodiment and its Modifications described above, the case where the first conductivity type is n-type and the second conductivity type is p-type has been exemplified, but the first conductivity type may be p-type and the second conductivity type may be n-type. In the embodiment and its Modifications described above, the case is shown in which the optical waveguide section 5 is a passive optical waveguide, but the optical waveguide section 5 may have a structure in which the refractive index is controlled by heater heating or the like. In the embodiment and its Modifications described above, the case is shown in which the protective mesa structure 62 is provided on both sides of the under-mesa region 51a in the lateral direction. However, the protective mesa structure 62 may not be provided, and the recesses 50 on both sides of the under-mesa region 51a may extend to the side edges of the substrate 2.

What is claimed is:

1. An optical modulator integrated laser device, comprising:
a semi-insulating or insulating substrate;
a laser section that is provided on the substrate and outputs laser light;
an optical modulator section that is provided on the substrate and receives the laser light from the laser section; and
an optical waveguide section that is provided on the substrate and optically couples the optical modulator section to the laser section,
wherein each of the laser section, the optical waveguide section, and the optical modulator section has:
a contact layer of a first conductivity type provided on the substrate;
a first cladding layer of the first conductivity type provided on the contact layer;
an optical waveguide layer provided on the first cladding layer; and
a second cladding layer of a second conductivity type provided on the optical waveguide layer,
in each of the laser section, the optical waveguide section, and the optical modulator section, the first cladding layer, the optical waveguide layer, and the second cladding layer form a mesa structure extending in an optical waveguide direction,
the contact layer includes an under-mesa region located between the mesa structure and the substrate, and
a width of the under-mesa region of the optical waveguide section in a first direction along the substrate which is perpendicular to the optical waveguide direction of the optical waveguide layer is smaller than both a width of the under-mesa region of the laser section in the first direction and a width of the under-mesa region of the optical modulator section in the first direction.

2. The optical modulator integrated laser device according to claim 1,
wherein the width of the under-mesa region of the optical waveguide section in the first direction is 1 μm or more and 8 μm or less.

3. The optical modulator integrated laser device according to claim 2,
wherein the width of the under-mesa region of the laser section in the first direction and the width of the under-mesa region of the optical modulator section in the first direction are 40 μm or more and 120 μm or less.

4. The optical modulator integrated laser device according to claim 1,
wherein a length of the under-mesa region of the optical waveguide section in the optical waveguide direction is 50 μm or more and 150 μm or less.

5. The optical modulator integrated laser device according to claim 1,
wherein the optical waveguide section further has a semi-insulating or insulating embedding region that embeds both sides of the mesa structure, and
both ends of the under-mesa region in the first direction are formed by a recess penetrating the embedding region and the contact layer.

6. The optical modulator integrated laser device according to claim 5,
wherein the optical waveguide section further has a protective mesa structure provided on both sides of the under-mesa region in the first direction, and
a height of the protective mesa structure with respect to the substrate is greater than a height of the optical waveguide layer with respect to the substrate.

7. The optical modulator integrated laser device according to claim 1,
wherein the optical modulator section includes a first optical modulator section and a second optical modulator section.

8. The optical modulator integrated laser device according to claim 1, further comprising:
a tip portion that is provided between the optical modulator section and a light emission end surface on the substrate and has the contact layer, the first cladding layer, the optical waveguide layer, and the second cladding layer,
wherein in the tip portion, the first cladding layer, the optical waveguide layer, and the second cladding layer form a mesa structure extending in the optical waveguide direction, the contact layer includes an under-mesa region located between the mesa structure and the substrate, and
a width of the under-mesa region of the tip portion in the first direction is smaller than both the width of the under-mesa region of the laser section in the first direction and the width of the under-mesa region of the optical modulator section in the first direction.

9. The optical modulator integrated laser device according to claim 1,
wherein an isolation resistance between the contact layer of the laser section and the contact layer of the optical modulator section is 200 Ω or more and 1 kΩ or less.
